(19) United States
(12) Patent Application Publication
(10) Pub. No.: US 2025/0391779 A1
(43) Pub. Date: Dec. 25, 2025

(54) SURFACE MOUNT POWER DEVICE AND FABRICATION METHOD THEREOF

(71) Applicant: Tong Hsing Electronic Industries, Ltd., Taoyuan City (TW)

(72) Inventor: Ting-An Yang, Taoyuan City (TW)

(73) Assignee: Tong Hsing Electronic Industries, Ltd., Taoyuan City (TW)

(21) Appl. No.: 18/792,566

(22) Filed: Aug. 2, 2024

(30) Foreign Application Priority Data
Jun. 25, 2024 (TW) 113123526

(51) Int. Cl. H01L 23/538; H01L 23/00; H01L 23/15; H01L 23/31; H01L 23/36; H01L 23/498; H01L 25/065

(52) U.S. Cl. CPC H01L 23/5386; H01L 23/49811; H01L 24/48; H01L 25/0655; H01L 23/15; H01L 23/3107; H01L 23/36; H01L 2224/48249

(57) ABSTRACT

A surface mount power device includes a substrate composed of an insulating core and a patterned metal layer, wherein the patterned metal layer includes a base island area and a lead area; a stepped feature is provided in the lead area, wherein the stepped feature includes a raised portion and a peripheral portion, and the peripheral portion is lower than the raised portion; a conductive material layer on the peripheral portion of the stepped feature; a semiconductor die attached onto the patterned metal layer within the base island area; a lead including a lead terminal bonded to the peripheral portion of the stepped feature through the conductive material layer; a bond wire connecting the semiconductor die to the raised portion of the stepped feature; and an encapsulant covering the substrate, the stepped feature, the semiconductor die, and the bond wire, and partially covering the lead.

### BACKGROUND OF THE INVENTION

### 1. Field of the Invention

The present invention relates to the field of semiconductor technology. In particularly, the present invention relates to an improved surface mount power device and a method for making the same.

### 2. Description of the Prior Art

Surface mount power devices (SMPDs) are electronic components designed for direct mounting onto printed circuit boards (PCBs) using surface mount technology (SMT). This approach offers a compelling combination: high performance, a compact footprint, and superior thermal management. These advantages make SMPDs ideal for a wide range of applications in power electronics.

To achieve this exceptional thermal performance, SMPDs are often assembled using substrates like direct copper bonding (DCB), direct bonded copper (DBC), active metal brazing (AMB), or direct plated copper (DPC) ceramic substrates. These substrates boast excellent thermal conductivity and minimal thermal resistance, enabling the SMPD package to efficiently dissipate heat away from its active components. Consequently, SMPD packages deliver higher power density and efficiency compared to traditional discrete component structures.

However, the current SMPD packaging process can be susceptible to lead frame tilt or warpage. This can lead to issues like the micro-bouncing effect, weak bonding force, or mold flash. These problems require further solutions to ensure optimal performance.

### SUMMARY OF THE INVENTION

It is one object of the present invention to provide an improved power semiconductor device so as to solve the deficiencies or shortcomings of the existing technology.

One aspect of the invention provides a surface mount power device including a substrate comprising a ceramic insulating core and a first patterned metal layer disposed on a first surface of the ceramic insulating core. The first patterned metal layer includes a base island area and a first lead area. At least one first stepped feature is disposed in the first lead area. The at least one first stepped feature includes a first raised portion and a first peripheral portion. The first peripheral portion is lower than the first raised portion. A first conductive material layer is disposed on the first peripheral portion of the first stepped feature. At least one semiconductor die is mounted on the first patterned metal layer in the base island area. At least one first lead includes a first lead terminal. The first lead terminal is bonded to the first peripheral portion of the first stepped feature through the first conductive material layer. At least one bond wire connects the at least one semiconductor die to the first raised portion of the first stepped feature. An encapsulant covers the substrate, the at least one first stepped feature, the at least one semiconductor die, the at least one bond wire, and at least partially covers the at least one first lead.

According to some embodiments, the first lead terminal has a Y-shaped structure that directly contacts the first conductive material layer.

According to some embodiments, the first peripheral portion is a half-etched, U-shaped recessed area that partially surrounds the first raised portion.

According to some embodiments, the first raised portion is closer to the base island area, and wherein the first raised portion is directly connected to the first peripheral portion, and wherein the first raised portion and the first peripheral portion are integrally formed to constitute the at least one first stepped feature.

According to some embodiments, the substrate includes a direct copper bonding (DCB) substrate, a direct bonded copper (DBC) substrate, an active metal brazing (AMB) substrate, or a direct plated copper (DPC) substrate.

According to some embodiments, the at least one semiconductor die includes an insulated gate bipolar transistor (IGBT), a power metal-oxide-semiconductor field-effect transistor (MOSFET), a bipolar junction transistor (BJT), a silicon carbide (SiC) power device, a gallium nitride (GaN) power device, a high electron mobility transistors (HEMT), or a fast recovery diode (FRD).

According to some embodiments, the surface mount power device further includes a second patterned metal layer disposed on a second surface of the ceramic insulating core.

According to some embodiments, the second patterned metal layer is exposed from one side of the encapsulant and is in direct contact with a heat-dissipating member.

In summary, the bonding joint in the wire bonding process is located on the raised portion of the first stepped feature, rather than on the first lead terminal. This effectively eliminates issues such as the micro-bouncing effect and poor wire bonding force. Additionally, the male-female wedge design between the first lead terminal and the raised portion facilitates precise and convenient installation positioning, preventing substrate offset or rotation. It also improves lead frame tilt or warpage, effectively addressing the mold flash issue.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 9 are schematic diagrams illustrating the manufacturing method of a surface mount power device according to an embodiment of the present invention. In particular, FIG. 7 is a side view schematic diagram after flipping the structure in FIG. 6 upside down, and FIG. 9 is a side view schematic diagram after flipping the structure in FIG. 8 upside down.

FIG. 10A, FIG. 10B, and FIG. 10C are partially enlarged schematic diagrams of the first stepped feature according to various embodiments.

FIG. 11A, FIG. 11B, and FIG. 11C are partially enlarged schematic diagrams of the first stepped feature and the first lead terminal after wire bonding, corresponding to FIG. 10A, FIG. 10B, and FIG. 10C, respectively.

FIG. 12 is a schematic, cross-sectional diagram of a surface mount power device according to an embodiment of the present invention.

### DETAILED DESCRIPTION

The following is a specific example to illustrate the implementation of the “surface mount power device and a fabrication method thereof” disclosed in the present invention. Those skilled in the art can understand the advantages and effects of the present invention from the content disclosed in this specification. The present invention can be implemented or applied through other different specific embodiments, and various details in this specification can also be modified and changed based on different viewpoints and applications without departing from the concept of the present invention. In addition, the drawings of the present invention are only simple schematic illustrations and are not depictions based on actual dimensions, as is stated in advance. The following embodiments will further describe the relevant technical content of the present invention in detail, but the disclosed content is not intended to limit the scope of the present invention.

It should be understood that although terms such as “first”, “second” and “third” may be used herein to describe various elements or signals, these elements or signals should not be limited by these terms. These terms are primarily used to distinguish one component from another component or one signal from another signal. In addition, the term “or” used in this article shall include any one or combination of more of the associated listed items depending on the actual situation.

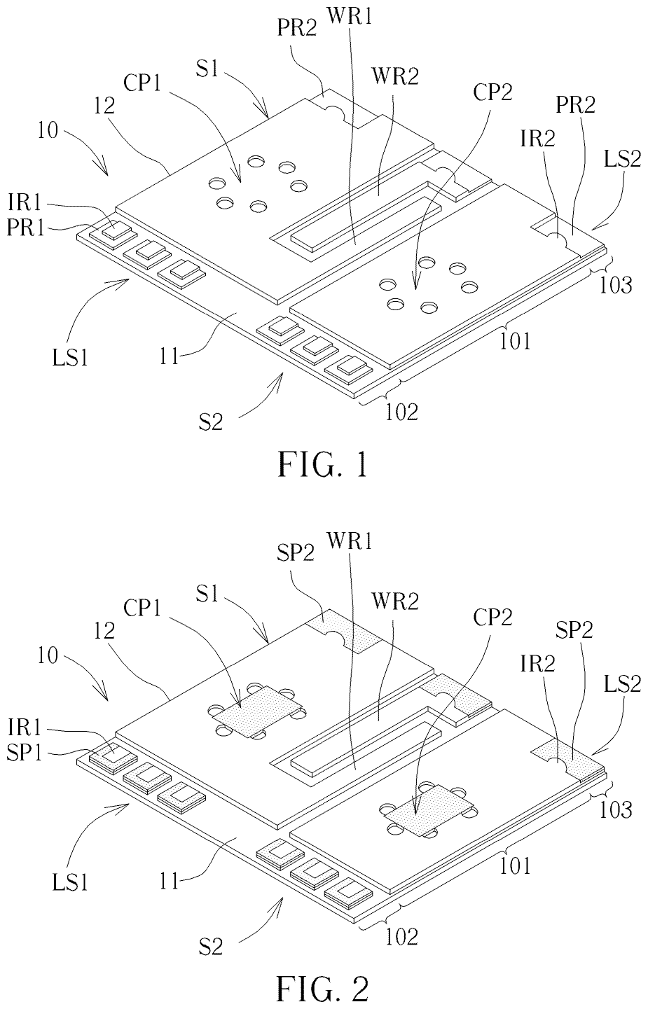

Please refer to FIG. 1 to FIG. 9, which are schematic diagrams illustrating an exemplary method for forming a surface mount power device according to an embodiment of the present invention. It is to be understood that a single-sided cooling (SSC) power device package structure is used as an example through FIG. 1 to FIG. 9 for illustration purposes only. The present invention is not limited to SSC power device package structure. Those skilled in the art should understand that the present invention can also be applied to other packaging forms, such as double-sided cooling (DSC) power device packaging structures or TOXX standard packaging structures.

As shown in FIG. 1, a substrate 10 is provided, which may comprise a ceramic insulating core 11 and a first patterned metal layer 12, for example, a patterned copper layer disposed on the first surface S1 of the ceramic insulating core 11. According to an embodiment of the present invention, a second patterned metal layer can be disposed on the second surface S2 of the ceramic insulating core 11 opposite to the first surface S1, for heat dissipation purposes (to be further explained later). For example, the aforementioned patterned copper metal layers disposed on the first surface S1 and the second surface S2 of the ceramic insulating core 11 can be formed using direct copper bonding (DCB), direct bonded copper (DBC), active metal brazing (AMB), or direct plated copper (DPC) technology, as needed, but are not limited thereto.

According to an embodiment of the present invention, the first patterned metal layer 12 disposed on the first surface S1 of the ceramic insulating core 11 may comprise, for example, a first chip mounting pad CP1 and a second chip mounting pad CP2 formed within the base island area 101; a first wire bonding area WR1 and a second wire bonding area WR2; and a plurality of first stepped features LS1 and a plurality of second stepped features LS2 formed in the first lead area 102 and the second lead area 103, respectively. The figures show 6 first stepped features LS1 and 3 second stepped features LS2. However, it should be understood that the number and layout of the above-mentioned first chip mounting pad CP1, second chip mounting pad CP2, first wire bonding area WR1, second wire bonding area WR2, first stepped feature LS1, and second stepped feature LS2 are for illustration purposes only, and the present invention is not limited thereto.

According to an embodiment of the present invention, for example, the plurality of first stepped features LS1 within the first lead area 102 can be disconnected from the large-area metal pattern formed within the base island area 101 without direct contact. According to an embodiment of the present invention, for example, the plurality of second stepped features LS2 within the second lead area 103 may not be disconnected from the large-area metal pattern formed within the base island area 101. In other words, the second stepped features LS2 may directly contact the metal pattern formed within the base island area 101. However, it should be understood that the above metal pattern layout is for illustration purposes only, and the present invention is not limited thereto.

According to an embodiment of the present invention, for example, the plurality of first stepped features LS1 within the first lead area 102 are arranged along one side of the substrate 10 and are spaced-apart from one another. According to an embodiment of the present invention, for example, each first stepped feature LS1 may comprise a first raised portion IR1 and a first peripheral portion PR1, wherein the first peripheral portion PR1 can be a half-etched, U-shaped recessed area that partially surrounds the first raised portion IR1. According to an embodiment of the present invention, the first raised portion IR1, which is closer to the base island area 101, is in direct connect with the U-shaped recessed first peripheral portion PR1. The first raised portion IR1 and the first peripheral portion PR1 are integrally formed and have a monolithic structure, thereby constituting the first stepped feature LS1.

According to an embodiment of the present invention, for example, the plurality of second stepped features LS2 within the second lead area 102 are arranged along the opposite side of the substrate 10, and the plurality of second stepped features LS2 are spaced apart from each other. According to an embodiment of the present invention, for example, each second stepped feature LS2 may comprise a second raised portion IR2 and a second peripheral portion PR2, wherein the second peripheral portion PR2 is also a half-etched, U-shaped recessed area that partially surrounds the second raised portion IR2. According to an embodiment of the present invention, the second raised portion IR2, which is directly connected to the base island area 101, and the second peripheral portion PR2, which is recessed in a U-shape, are integrally formed in structure to form the second stepped feature LS2.

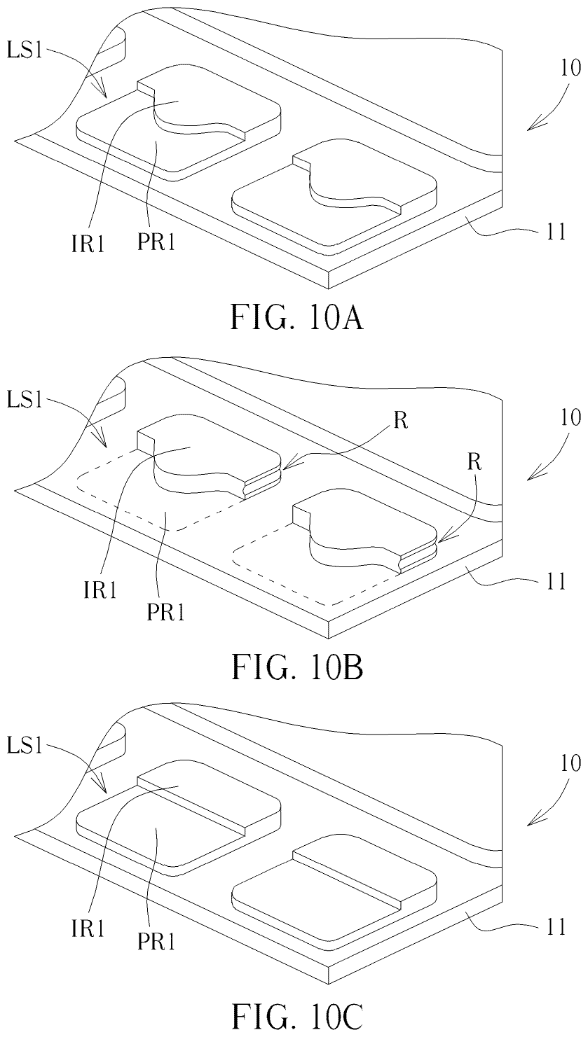

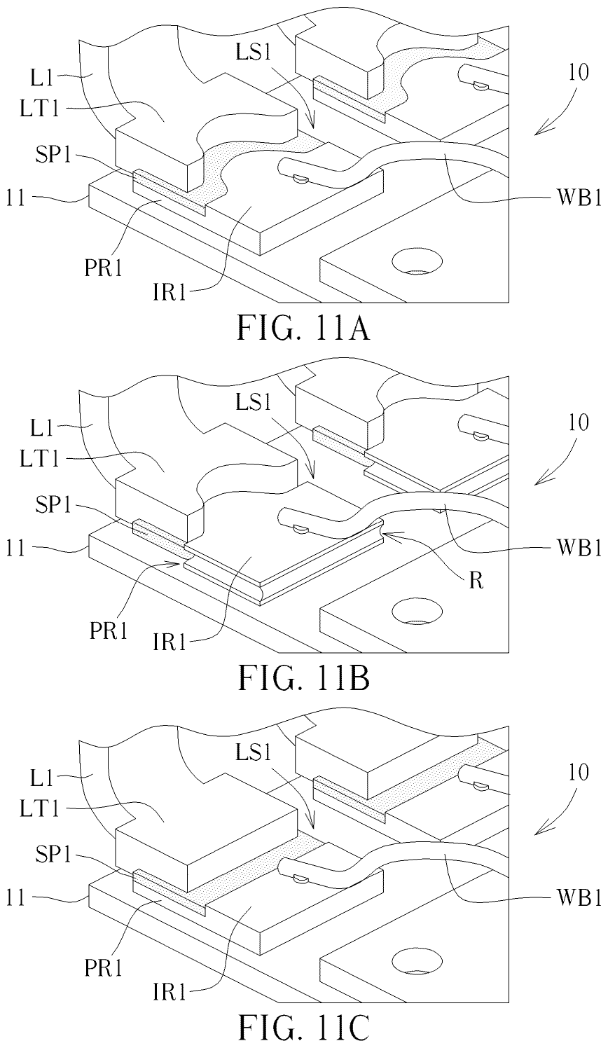

Please also refer to FIG. 10A to FIG. 10C, which are enlarged schematic diagrams of the first stepped feature LS1 according to various embodiments. Those skilled in the art should understand, the plurality of second stepped features LS2 located on the other side of the substrate 10 can also have a structure similar to that shown in FIG. 10A to FIG. 10C. For the sake of simplicity, they are not described in detail below.

As shown in FIG. 10A, the first stepped feature LS1 comprises a first raised portion IR1 and a first peripheral portion PR1. The first raised portion IR1 may have a semicircular structure extending outward towards the edge of the substrate 10, and the first peripheral portion PR1 may be a U-shaped recessed area formed by half-etching, partially surrounding the first raised portion IR1. The upper surface of the first peripheral portion PR1 is lower than the upper surface of the first raised portion IR1. According to an embodiment of the present invention, the first raised portion IR1, which is closer to the base island area 101, is directly connected to the U-shaped, recessed first peripheral portion PR1, and they are integrally formed in structure.

As shown in FIG. 10B, the first stepped feature LS1 includes a first raised portion IR1 and a first peripheral portion PR1. The first raised portion IR1 may have a semicircular structure that extends outward towards the edge of the substrate 10. The first peripheral portion PR1 may be a fully etched U-shaped region (as shown by the dashed line), and the first peripheral portion PR1 partially surrounds the first raised portion IR1. The first peripheral portion PR1 is defined by a portion of the first surface S1 of the ceramic insulating core 11. In other words, the first peripheral portion PR1 does not include the copper metal layer. According to an embodiment of the present invention, the sidewall of the first raised portion IR1 can have a recessed feature R.

As shown in FIG. 10C, likewise, the first stepped feature LS1 comprises a first raised portion IR1 and a first peripheral portion PR1. In FIG. 10A, the first raised portion IR1 has a semicircular structure extending towards the edge of the substrate 10, while in FIG. 10C, the junction between the first raised portion IR1 and the first peripheral portion PR1 is straight. The first peripheral portion PR1 may be a recessed area formed by half-etching. The upper surface of the first peripheral portion PR1 is lower than the upper surface of the first raised portion IR1. According to an embodiment of the present invention, the first raised portion IR1, which is closer to the base island area 101, is directly connected to the recessed first peripheral portion PR1, and they are integrally formed in structure.

As shown in FIG. 2, a first conductive material layer SP1 and a second conductive material layer SP2 are then formed on the first peripheral portion PR1 of the first stepped feature LS1 and the second peripheral portion PR2 of the second stepped feature LS2, respectively. According to an embodiment of the present invention, the first conductive material layer SP1 and the second conductive material layer SP2 may include, but are not limited to, solder paste or pressure-less silver sintering paste. According to an embodiment of the present invention, for example, the first conductive material layer SP1 and the second conductive material layer SP2 can be formed on the first peripheral portion PR1 and the second peripheral portion PR2, respectively, using a printing method. According to an embodiment of the present invention, for example, the aforementioned printing method may include screen printing or inkjet printing, but is not limited thereto. According to an embodiment of the present invention, for example, the upper surface of the first conductive material layer SP1 and the upper surface of the second conductive material layer SP2 may be coplanar with the upper surface of the first raised portion IR1 and the upper surface of the second raised portion IR2, respectively. According to some embodiments of the present invention, for example, the upper surface of the first conductive material layer SP1 and the upper surface of the second conductive material layer SP2 may be lower than the upper surface of the first raised portion IR1 and the upper surface of the second raised portion IR2, respectively.

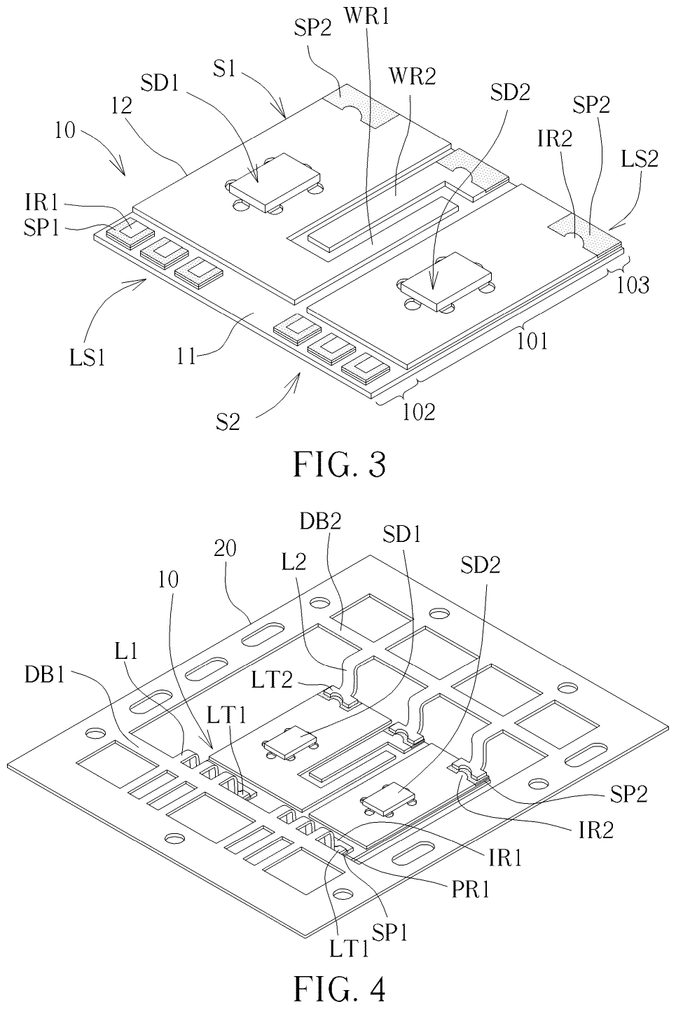

As shown in FIG. 3, a first semiconductor die SD1 and a second semiconductor die SD2 are then attached onto the first chip mounting pad CP1 and the second chip mounting pad CP2 in the base island area 101. According to an embodiment of the present invention, for example, the first semiconductor die SD1 and the second semiconductor die SD2 may be power chips, but are not limited thereto. The type of the power chip can be adjusted and changed according to actual needs. For example, the power chip can be an insulated gate bipolar transistor (IGBT), a power metal-oxide-semiconductor field-effect transistor (MOSFET), a bipolar junction transistor (BJT), a silicon carbide (SiC) power device, a gallium nitride (GaN) power device, a high electron mobility transistor (HEMT), or a fast recovery diode (FRD).

As shown in FIG. 4, a lead frame 20 is then mounted onto the substrate 10. According to an embodiment of the present invention, the lead frame 20 is a metal frame, typically made of copper or a copper alloy, formed by stamping or etching to include a plurality of first leads L1 and a plurality of second leads L2 that are respectively connected to a first dam bar DB1 and a second dam bar DB2. According to an embodiment of the present invention, the first leads L1 and the second leads L2 respectively have first lead terminals LT1 and second lead terminals LT2, which are respectively bonded to the first peripheral portions PR1 of the first stepped features LS1 and the second peripheral portions PR2 of the second stepped features LS2. For example, the first lead terminals LT1 and the second lead terminals LT2 may have a Y-shaped structure and respectively directly contact the first conductive material layer SP1 and the second conductive material layer SP2. Alternatively, the first lead terminals LT1 and the second lead terminals LT2 may have a Y-shaped structure and respectively bonded to the first peripheral portions PR1 of the first stepped features LS1 and the second peripheral portions PR2 of the second stepped features LS2 by welding instead of soldering or sintering using the first conductive material layer SP1 and the second conductive material layer SP2.

Subsequently, vacuum reflow and flux cleaning steps can be performed to form sturdy solder joints. According to an embodiment of the present invention, the first lead terminal LT1 and the second lead terminal LT2 do not directly contact the raised portion IR1 of the first stepped feature LS1 and the raised portion IR2 of the second stepped feature LS2, respectively.

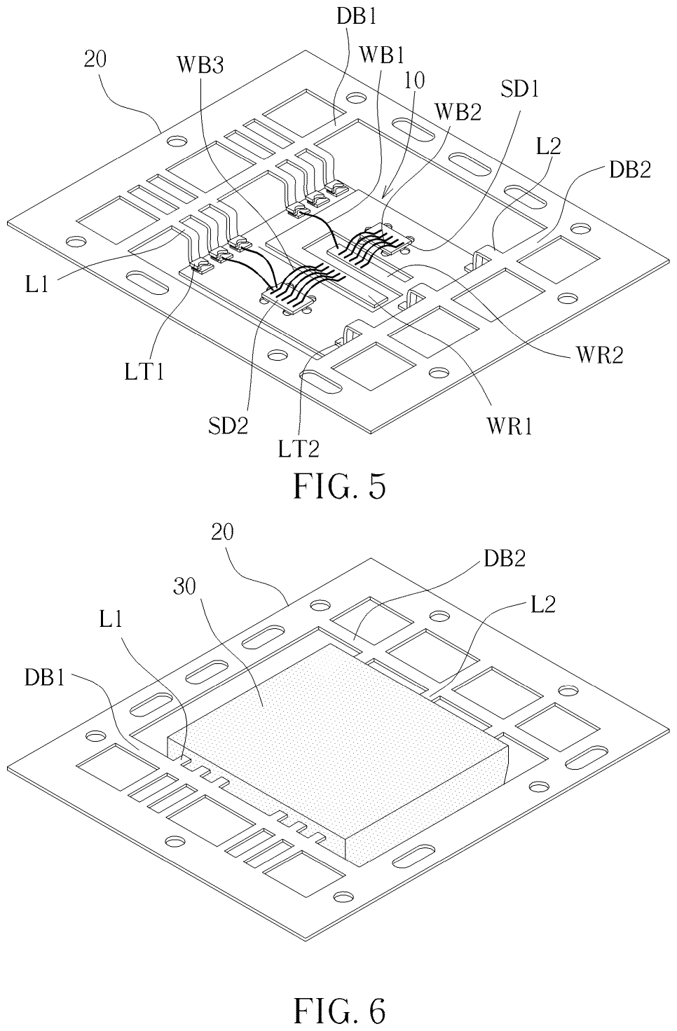

As shown in FIG. 5, next, a wire bonding process, such as wedge bonding, is performed to form a plurality of first bond wires WB1 between the first semiconductor die SD1 and the raised portion IR1 of the corresponding first stepped feature LS1, as well as between the second semiconductor die SD2 and the raised portion IR1 of the corresponding first stepped feature LS1. A second bond wire WB2 is formed between the first semiconductor die SD1 and the second bonding area WR2, and a third bond wire WB3 is formed between the second semiconductor die SD2 and the first bonding area WR1. According to an embodiment of the present invention, the first bond wire WB1, the second bond wire WB2, and the third bond wire WB3 may comprise gold wire or copper wire, but are not limited thereto.

Please also refer to FIG. 11A to FIG. 11C, which are enlarged schematic diagrams of the stepped feature LS1 and the first lead terminal LT1 after wire bonding, corresponding to FIG. 10A to FIG. 10C. As shown in FIG. 11A, one end of the first bond wire WB1 is directly bonded to the raised portion IR1 of the first stepped feature LS1, and the end of the first bond wire WB1 is kept a distance from the first lead terminal LT1. As shown in FIG. 11B, likewise, one end of the first bond wire WB1 is directly bonded to the raised portion IR1 of the first stepped feature LS1, and is kept a distance from the first lead terminal LT1. In addition, the first conductive material layer SP1 can overflow to the recessed feature R on the sidewall of the raised portion IR1 by capillary action, further enhancing the stability of the bonding structure. As shown in FIG. 11C, likewise, one end of the first bond wire WB1 is directly bonded to the raised portion IR1 of the first stepped feature LS1, and is kept a distance from the first lead terminal LT1.

Due to the fact that the wire bonding joint is located on the raised portion IR1 of the first stepped feature LS1 in the wire bonding process, rather than on the first lead terminal LT1, the micro-bouncing effect and poor wire bonding force can be effectively avoided. In addition, the male-female wedge design between the Y-shaped first lead terminal LT1 and the raised portion IR1, as shown in FIG. 11A and FIG. 11B, facilitates precise and convenient installation positioning, prevents substrate offset or rotation, and improves lead frame tilt or warpage, effectively addressing the mold flash issue.

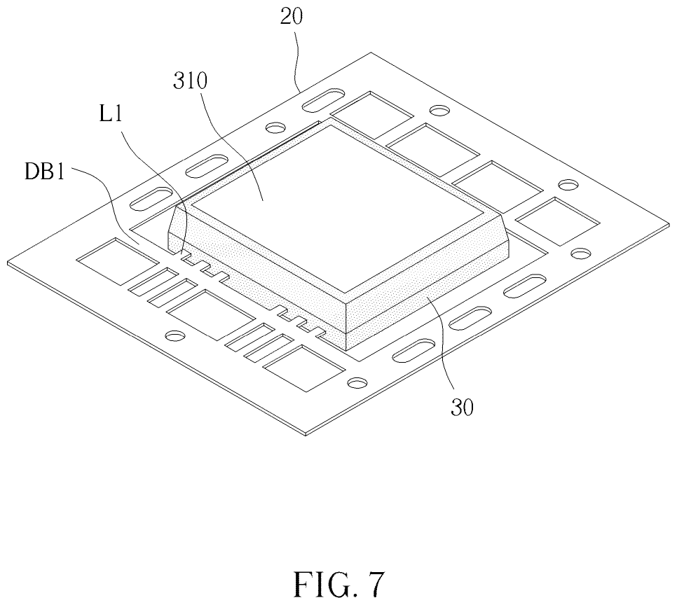

As shown in FIG. 6 and FIG. 7, a molding process, such as film-assisted molding (FAM), is then performed to encapsulate the substrate 10, the first semiconductor die SD1, the second semiconductor die SD2, the first bond wire WB1, the second bond wire WB2, the third bond wire WB3, a part of the first lead L1, and a part of the second lead L2 with a molding compound, thereby forming an encapsulant 30. As can be seen from FIG. 7, a heat-dissipating member 310 can be formed on one side of the encapsulant 30, which is in direct contact with a copper metal layer on the second surface S2 of the ceramic insulating core 11.

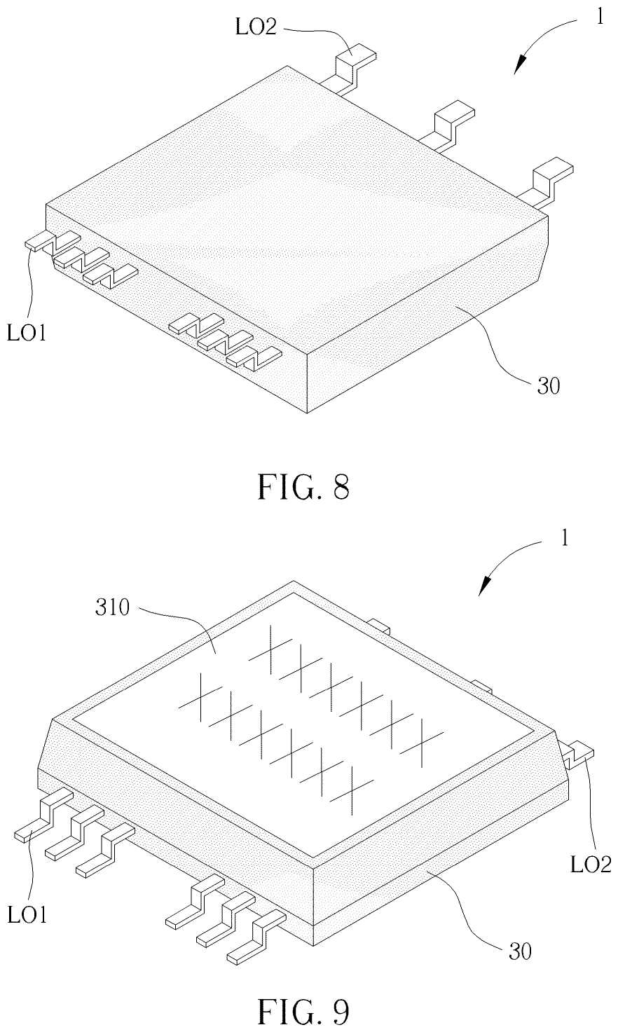

As shown in FIG. 8 and FIG. 9, next, a marking process, a dam bar cutting process, a dejunk trimming process, and a tin plating process can be performed to form a surface mount power device 1, which includes gullwing-shaped first pin LO1 and second pin LO2 protruding from the two end faces of the encapsulant 30.

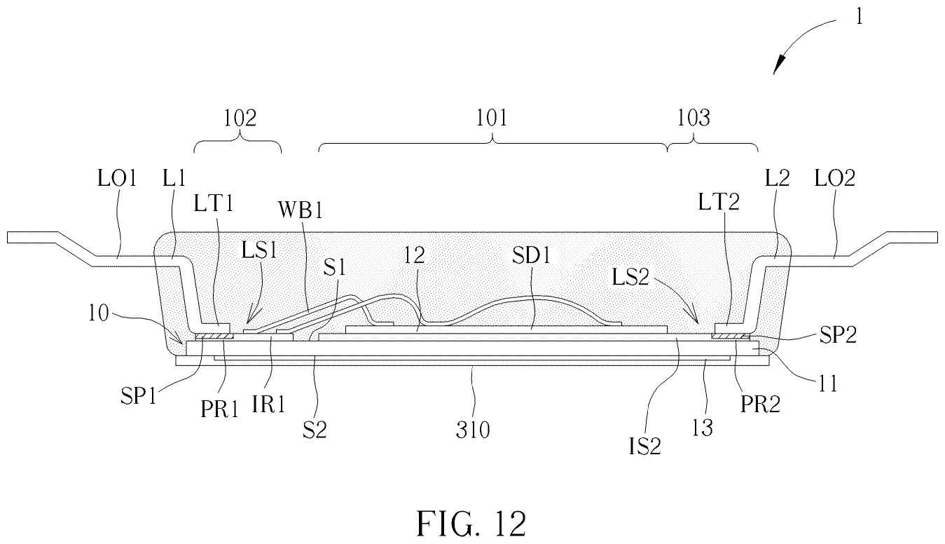

Please refer to FIG. 12, which is a schematic diagram of the cross-sectional structure of a surface mount power device illustrated according to an embodiment of the present invention, wherein like regions, materials, and layers are designated by like numeral numbers or labels. As shown in FIG. 12, the surface mount power device 1 comprises a substrate 10. According to an embodiment of the present invention, for example, the substrate 10 comprises a ceramic insulating core 11, a first patterned metal layer 12 disposed on the first surface S1 of the ceramic insulating core 11, and a second patterned metal layer 13 disposed on the second surface S2 of the ceramic insulating core 11. The substrate 10 may be a direct copper bonding (DCB) substrate, a direct bonded copper (DBC) substrate, an active metal brazing (AMB) substrate, or a direct plated copper (DPC) substrate, but is not limited thereto.

According to an embodiment of the present invention, the first patterned metal layer 12 comprises a base island area 101, a first lead area 102, and a second lead area 103. At least one first stepped feature LS1 and at least one second stepped feature LS2 are respectively disposed within the first lead area 102 and the second lead area 103. According to an embodiment of the present invention, for example, the first stepped feature LS1 may comprise a first raised portion IR1 and a first peripheral portion PR1, wherein the first peripheral portion PR1 is lower than the first raised portion IR1. For example, the first peripheral portion PR1 can be a half-etched, U-shaped recessed area that partially surrounds the first raised portion IR1. According to an embodiment of the present invention, the first raised portion IR1, which is closer to the base island area 101, is directly connected to the U-shaped recessed first peripheral portion PR1, and the two are integrally formed to constitute the first stepped feature LS1.

According to an embodiment of the present invention, for example, the second stepped feature LS2 may include a second raised portion IR2 and a second peripheral portion PR2. The second peripheral portion PR2 is also a U-shaped recessed area formed by half-etching, partially surrounding the second raised portion IR2. According to an embodiment of the present invention, the second raised portion IR2, which is directly connected to the first patterned metal layer 12 in the base island area 101, and the U-shaped recessed second peripheral portion PR2 are integrally formed in structure to form the second stepped feature LS2.

According to an embodiment of the present invention, for example, a first conductive material layer SP1 and a second conductive material layer SP2 are respectively disposed on the first peripheral portion PR1 of the first stepped feature LS1 and the second peripheral portion PR2 of the second stepped feature LS2. According to an embodiment of the present invention, the first conductive material layer SP1 and the second conductive material layer SP2 may comprise, but are not limited to, solder paste or pressure-less silver sintering paste.

According to an embodiment of the present invention, the surface mount power device 1 further comprises a first semiconductor die SD1 mounted on the first patterned metal layer 12 within the base island area 101. According to an embodiment of the present invention, for example, the first semiconductor die SD1 can be a power chip, but is not limited thereto. The type of power chip can be adjusted and changed according to actual needs. For example, the power chip can be an insulated gate bipolar transistor (IGBT), a power metal-oxide-semiconductor field-effect transistor (MOSFET), a bipolar junction transistor (BJT), a silicon carbide (SiC) power device, a gallium nitride (GaN) power device, a high electron mobility transistor (HEMT), or a fast recovery diode (FRD).

According to an embodiment of the present invention, the surface mount power device 1 further comprises at least one first lead L1 and at least one second lead L2. According to an embodiment of the present invention, for example, the first lead L1 and the second lead L2 respectively have a first lead terminal LT1 and a second lead terminal LT2, which are respectively bonded to the first peripheral portion PR1 of the first stepped feature LS1 and the second peripheral portion PR2 of the second stepped feature LS2 through the first conductive material layer SP1 and the second conductive material layer SP2. For example, the first lead terminal LT1 and the second lead terminal LT2 may have a Y-shaped structure and directly contact the first conductive material layer SP1 and the second conductive material layer SP2, respectively. After sintering, a sturdy solder joint is formed.

According to an embodiment of the present invention, the first lead terminal LT1 and the second lead terminal LT2 do not directly contact the first raised portion IR1 of the first stepped feature LS1 and the second raised portion IR2 of the second stepped feature LS2.

According to an embodiment of the present invention, the surface mounted power device 1 further comprises at least one first bond wire WB1 connecting the first semiconductor die SD1 to the first raised portion IR1 of the first stepped feature LS1. According to an embodiment of the present invention, the first bond wire WB1 may comprise gold wire or copper wire, but is not limited thereto.

According to an embodiment of the present invention, surface mount power device 1 further comprises an encapsulant 30 that encloses substrate 10, the first semiconductor die SD1, the first bond wire WB1, a portion of first lead L1, and a portion of second lead L2. According to an embodiment of the present invention, the second patterned metal layer 13 of substrate 10 may be exposed. A heat-dissipating member 310 can be formed on one side of the encapsulant 30, which is in direct contact with the second patterned metal layer 13. The other ends of first lead L1 and the second lead L2 extend out from the two opposite sides of the encapsulant 30 to form first pins LO1 and second pins LO2, respectively.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A surface mount power device, comprising:
a substrate, comprising a ceramic insulating core and a first patterned metal layer disposed on a first surface of the ceramic insulating core, wherein the first patterned metal layer comprises a base island area and a first lead area;
at least one first stepped feature disposed in the first lead area, wherein the at least one first stepped feature comprises a first raised portion and a first peripheral portion, wherein the first peripheral portion is lower than the first raised portion;
a first conductive material layer disposed on the first peripheral portion of the first stepped feature;
at least one semiconductor die mounted on the first patterned metal layer in the base island area;
at least one first lead comprising a first lead terminal, wherein the first lead terminal is bonded to the first peripheral portion of the first stepped feature through the first conductive material layer;
at least one bond wire connecting the at least one semiconductor die to the first raised portion of the first stepped feature; and
an encapsulant covering the substrate, the at least one first stepped feature, the at least one semiconductor die, the at least one bond wire, and at least partially covering the at least one first lead.

2. The surface mount power device according to claim 1, wherein the first lead terminal has a Y-shaped structure that directly contacts the first conductive material layer, and wherein the first peripheral portion is a half-etched, U-shaped recessed area that partially surrounds the first raised portion.

3. The surface mount power device according to claim 1, wherein the first raised portion is closer to the base island area, and wherein the first raised portion is directly connected to the first peripheral portion, and wherein the first raised portion and the first peripheral portion are integrally formed to constitute the at least one first stepped feature.

4. The surface mount power device according to claim 1, wherein the substrate comprises a direct copper bonding (DCB) substrate, a direct bonded copper (DBC) substrate, an active metal brazing (AMB) substrate, or a direct plated copper (DPC) substrate.

5. The surface mount power device according to claim 1, wherein the first conductive material layer comprises solder paste or pressure-less silver sintering paste.

6. The surface mount power device of claim 1, wherein the first lead terminal is not in direct contact with the first raised portion of the first stepped feature.

7. The surface mount power device according to claim 1, wherein the first patterned metal layer further comprises a second lead area.

8. The surface mount power device according to claim 7, further comprising at least one second stepped feature disposed in the second lead area, and the at least one second stepped feature comprises a second raised portion and a second peripheral portion, and wherein the second peripheral part is a half-etched, U-shaped recessed area that partially surrounds the second raised portion.

9. The surface mount power device according to claim 8, wherein the second raised portion is directly connected to the first patterned metal layer in the base island area, and the second raised portion and the second peripheral portion are integral formed to constitute the at least one second stepped feature.

10. The surface mount power device according to claim 8, further comprising a second conductive material layer disposed on the second peripheral portion of the second stepped feature, and wherein the second conductive material layer comprises solder paste or pressure-less silver sinter paste.

11. The surface mount power device according to claim 10, further comprising at least one second lead, wherein the at least one second lead comprises a second lead terminal bonded to the second peripheral portion of the second stepped feature through the second conductive material layer.

12. The surface mount power device of claim 11, wherein the second lead terminal is not in direct contact with the second raised portion of the second stepped feature.

13. The surface mount power device according to claim 1, further comprising a second patterned metal layer disposed on a second surface of the ceramic insulating core.

14. The surface mount power device according to claim 13, wherein the second patterned metal layer is exposed from one side of the encapsulant and is in direct contact with a heat-dissipating member.
